(19) United States
(12) Patent Application Publication
(10) Pub. No.: US 2024/0137154 A1
(43) Pub. Date: Apr. 25, 2024

(54) BIT SCRAMBLING FOR PROBABILISTIC CONSTELLATION SHAPING IN WLANS

(71) Applicants: Qinghua Li, San Ramon, CA (US); Hao Song, Santa Clara, CA (US); Danny Alexander, Neve Efraim Monoson (IL); Shlomi Vituri, Tel Aviv (IL); Assaf Gurevitz, Ramat Hasharon (IL); Robert J. Stacey, Portland, OR (US)

(72) Inventors: Qinghua Li, San Ramon, CA (US); Hao Song, Santa Clara, CA (US); Danny Alexander, Neve Efraim Monoson (IL); Shlomi Vituri, Tel Aviv (IL); Assaf Gurevitz, Ramat Hasharon (IL); Robert J. Stacey, Portland, OR (US)

(21) Appl. No.: 18/400,461

(22) Filed: Dec. 29, 2023

(51) Int. Cl. H04L 1/00; H04L 27/34; H04W 84/12

(52) U.S. Cl. CPC H04L 1/0063; H04L 1/0042; H04L 27/3483; H04W 84/12

(57) ABSTRACT

A station (STA) configured for operation in a WLAN may perform bit scrambling on input bits to generate scrambled input bits and may perform probabilistic constellation shaping using a shaping encoder on the scrambled input bits. The shaping encoder may encode a segment of the scrambled input bits for a modulation order and generate a shaped bit stream. In these embodiments, the STA may generate a QAM symbol stream with a QAM modulator. The QAM symbol stream may be generated at least from the shaped bit stream and from parity bits using the modulation order. The STA may generate the parity bits from the shaped bit streams with a forward-error correction (FEC) encoder and may transmit the QAM symbol stream within a physical layer protocol data unit (PPDU). To address a potential byte boundary shift caused a decoding error at a receiving station, the STA may modify performance of the bit scrambling when probabilistic constellation shaping is performed.

### TECHNICAL FIELD

Embodiments pertain to wireless communications. Some embodiments relate to wireless local area networks (WLANS).

### BACKGROUND

Future wireless local area networks (WLANS) (e.g., Wi-Fi 8 and beyond) are expected to achieve higher performance levels that conventional WLANS. These higher performance level may include higher-data rates, improved spectral efficiency, and improved network efficiencies. One technique to improve WLAN performance is bit scrambling. Bit scrambling helps improve power efficiency, security, synchronization, robustness, and compliance in WLANs. The randomness and reduced interference help the wireless network better coexist with other electronics. Another technique to improve WLAN performance is constellation shaping. Constellation shaping improves spectral efficiency and provides an effective way to improve throughput, resilience, latency and efficiency in WLANs.

### BRIEF DESCRIPTION OF THE DRAWINGS

FIG. 1 is a block diagram of a radio architecture, in accordance with some embodiments.

FIG. 2 illustrates a front-end module circuitry for use in the radio architecture of FIG. 1, in accordance with some embodiments.

FIG. 3 illustrates a radio IC circuitry for use in the radio architecture of FIG. 1, in accordance with some embodiments.

FIG. 4 illustrates a baseband processing circuitry for use in the radio architecture of FIG. 1, in accordance with some embodiments.

FIG. 5 illustrates a WLAN, in accordance with some embodiments.

FIG. 6 illustrates probabilistic constellation shaping, in accordance with some embodiments.

FIG. 7 illustrates bit shift due to a decoding error, in accordance with some embodiments.

FIG. 8 illustrates the scrambling of input data bits, in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Some embodiments are directed to a station (STA) configured for operation in a WLAN. In these embodiments, the STA may perform bit scrambling on input bits to generate scrambled input bits and may perform probabilistic constellation shaping using a shaping encoder on the scrambled input bits. In these embodiments, the shaping encoder may encode a segment of the scrambled input bits for a modulation order and generate a shaped bit stream. In these embodiments, the STA may generate a QAM symbol stream with a QAM modulator. The QAM symbol stream may be generated at least from the shaped bit stream and from parity bits using the modulation order. In these embodiments, the STA may generate the parity bits from the shaped bit streams with a forward-error correction (FEC) encoder and may transmit the QAM symbol stream within a physical layer protocol data unit (PPDU). In these embodiments, to address a potential byte boundary shift caused a decoding error at a receiving station, the STA may modify performance of the bit scrambling when probabilistic constellation shaping is performed. In these embodiments, bit scrambling may help reduce the PAPR of the transmitted signal.

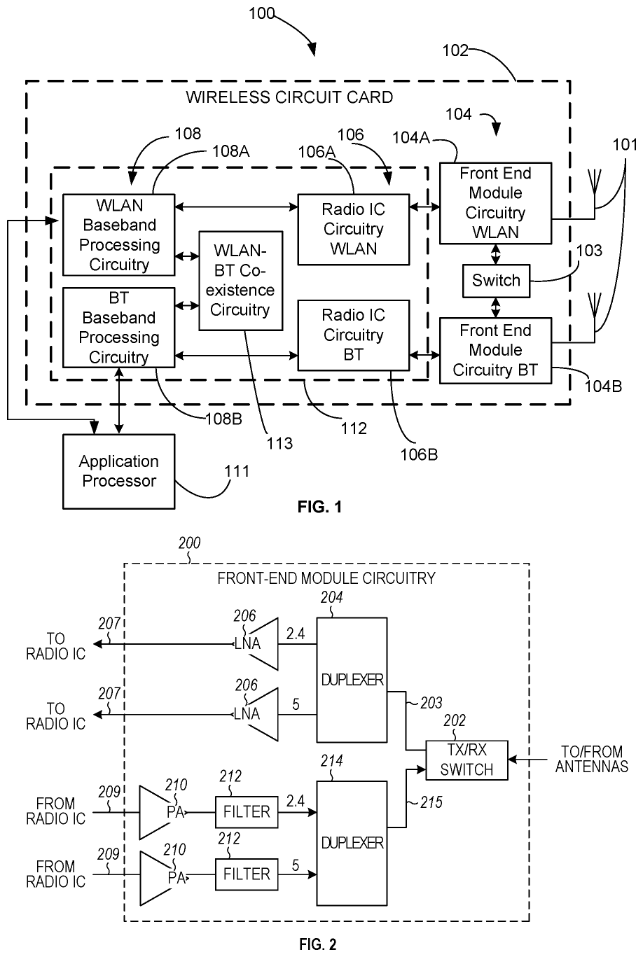

FIG. 1 is a block diagram of a radio architecture 100 in accordance with some embodiments. Radio architecture 100 may include radio front-end module (FEM) circuitry 104, radio IC circuitry 106 and baseband processing circuitry 108. Radio architecture 100 as shown includes both Wireless Local Area Network (WLAN) functionality and Bluetooth (BT) functionality although embodiments are not so limited. In this disclosure, “WLAN” and “Wi-Fi” are used interchangeably.

FEM circuitry 104 may include a WLAN or Wi-Fi FEM circuitry 104A and a Bluetooth (BT) FEM circuitry 104B. The WLAN FEM circuitry 104A may include a receive signal path comprising circuitry configured to operate on WLAN RF signals received from one or more antennas 101, to amplify the received signals and to provide the amplified versions of the received signals to the WLAN radio IC circuitry 106A for further processing. The BT FEM circuitry 104B may include a receive signal path which may include circuitry configured to operate on BT RF signals received from one or more antennas 101, to amplify the received signals and to provide the amplified versions of the received signals to the BT radio IC circuitry 106B for further processing. FEM circuitry 104A may also include a transmit signal path which may include circuitry configured to amplify WLAN signals provided by the radio IC circuitry 106A for wireless transmission by one or more of the antennas 101. In addition, FEM circuitry 104B may also include a transmit signal path which may include circuitry configured to amplify BT signals provided by the radio IC circuitry 106B for wireless transmission by the one or more antennas. In the embodiment of FIG. 1, although FEM CIRCUITRY 104A and FEM CIRCUITRY 104B are shown as being distinct from one another, embodiments are not so limited, and include within their scope the use of an FEM (not shown) that includes a transmit path and/or a receive path for both WLAN and BT signals, or the use of one or more FEM circuitries where at least some of the FEM circuitries share transmit and/or receive signal paths for both WLAN and BT signals.

Radio IC circuitry 106 as shown may include WLAN radio IC circuitry 106A and BT radio IC circuitry 106B. The WLAN radio IC circuitry 106A may include a receive signal path which may include circuitry to down-convert WLAN RF signals received from the FEM circuitry 104A and provide baseband signals to WLAN baseband processing circuitry 108A. BT radio IC circuitry 106B may in turn include a receive signal path which may include circuitry to down-convert BT RF signals received from the FEM circuitry 104B and provide baseband signals to BT baseband processing circuitry 108B. WLAN radio IC circuitry 106A may also include a transmit signal path which may include circuitry to up-convert WLAN baseband signals provided by the WLAN baseband processing circuitry 108A and provide WLAN RF output signals to the FEM circuitry 104A for subsequent wireless transmission by the one or more antennas 101. BT radio IC circuitry 106B may also include a transmit signal path which may include circuitry to up-convert BT baseband signals provided by the BT baseband processing circuitry 108B and provide BT RF output signals to the FEM circuitry 104B for subsequent wireless transmission by the one or more antennas 101. In the embodiment of FIG. 1, although radio IC circuitries 106A and 106B are shown as being distinct from one another, embodiments are not so limited, and include within their scope the use of a radio IC circuitry (not shown) that includes a transmit signal path and/or a receive signal path for both WLAN and BT signals, or the use of one or more radio IC circuitries where at least some of the radio IC circuitries share transmit and/or receive signal paths for both WLAN and BT signals.

Baseband processing circuitry 108 may include a WLAN baseband processing circuitry 108A and a BT baseband processing circuitry 108B. The WLAN baseband processing circuitry 108A may include a memory, such as, for example, a set of RAM arrays in a Fast Fourier Transform or Inverse Fast Fourier Transform block (not shown) of the WLAN baseband processing circuitry 108A. Each of the WLAN baseband circuitry 108A and the BT baseband circuitry 108B may further include one or more processors and control logic to process the signals received from the corresponding WLAN or BT receive signal path of the radio IC circuitry 106, and to also generate corresponding WLAN or BT baseband signals for the transmit signal path of the radio IC circuitry 106. Each of the baseband processing circuitries 108A and 108B may further include physical layer (PHY) and medium access control layer (MAC) circuitry and may further interface with application processor 111 for generation and processing of the baseband signals and for controlling operations of the radio IC circuitry 106.

Referring still to FIG. 1, according to the shown embodiment, WLAN-BT coexistence circuitry 113 may include logic providing an interface between the WLAN baseband circuitry 108A and the BT baseband circuitry 108B to enable use cases requiring WLAN and BT coexistence. In addition, a switch 103 may be provided between the WLAN FEM circuitry 104A and the BT FEM circuitry 104B to allow switching between the WLAN and BT radios according to application needs. In addition, although the antennas 101 are depicted as being respectively connected to the WLAN FEM circuitry 104A and the BT FEM circuitry 104B, embodiments include within their scope the sharing of one or more antennas as between the WLAN and BT FEMs, or the provision of more than one antenna connected to each of FEM circuitry 104A or FEM circuitry 104B.

In some embodiments, the front-end module circuitry 104, the radio IC circuitry 106, and baseband processing circuitry 108 may be provided on a single radio card, such as wireless radio card 102. In some other embodiments, the one or more antennas 101, the FEM circuitry 104 and the radio IC circuitry 106 may be provided on a single radio card. In some other embodiments, the radio IC circuitry 106 and the baseband processing circuitry 108 may be provided on a single chip or integrated circuit (IC), such as IC 112.

In some embodiments, the wireless radio card 102 may include a WLAN radio card and may be configured for Wi-Fi communications, although the scope of the embodiments is not limited in this respect. In some of these embodiments, the radio architecture 100 may be configured to receive and transmit orthogonal frequency division multiplexed (OFDM) or orthogonal frequency division multiple access (OFDMA) communication signals over a multicarrier communication channel. The OFDM or OFDMA signals may comprise a plurality of orthogonal subcarriers.

In some of these multicarrier embodiments, radio architecture 100 may be part of a Wi-Fi communication station (STA) such as a wireless access point (AP), a base station or a mobile device including a Wi-Fi device. In some of these embodiments, radio architecture 100 may be configured to transmit and receive signals in accordance with specific communication standards and/or protocols, such as any of the Institute of Electrical and Electronics Engineers (IEEE) standards including, IEEE 802.11n-2009, IEEE 802.11-2012, IEEE 802.11-2016, IEEE 802.11ac, IEEE 802.11ax, and/or IEEE P802.11be standards and/or proposed specifications for WLANs, although the scope of embodiments is not limited in this respect. Radio architecture 100 may also be suitable to transmit and/or receive communications in accordance with other techniques and standards.

In some embodiments, the radio architecture 100 may be configured for high-efficiency (HE) Wi-Fi (HEW) communications in accordance with the IEEE 802.11ax standard. In some embodiments, the radio architecture 100 may be configured for Extremely High Throughput (EHT) communications in accordance with the IEEE 802.11be standard. In these embodiments, the radio architecture 100 may be configured to communicate in accordance with an OFDMA technique, although the scope of the embodiments is not limited in this respect. In some embodiments, the radio architecture 100 may be configured for next generation vehicle-to-everything (NGV) communications in accordance with the IEEE 802.11bd standard and one or more stations including AP 502 may be next generation vehicle-to-everything (NGV) stations (STAs).

In some other embodiments, the radio architecture 100 may be configured to transmit and receive signals transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

In some embodiments, as further shown in FIG. 1, the BT baseband circuitry 108B may be compliant with a Bluetooth (BT) connectivity standard such as Bluetooth, Bluetooth 4.0 or Bluetooth 5.0, or any other iteration of the Bluetooth Standard. In embodiments that include BT functionality as shown for example in FIG. 1, the radio architecture 100 may be configured to establish a BT synchronous connection oriented (SCO) link and/or a BT low energy (BT LE) link. In some of the embodiments that include functionality, the radio architecture 100 may be configured to establish an extended SCO (eSCO) link for BT communications, although the scope of the embodiments is not limited in this respect. In some of these embodiments that include a BT functionality, the radio architecture may be configured to engage in a BT Asynchronous Connection-Less (ACL) communications, although the scope of the embodiments is not limited in this respect. In some embodiments, as shown in FIG. 1, the functions of a BT radio card and WLAN radio card may be combined on a single wireless radio card, such as single wireless radio card 102, although embodiments are not so limited, and include within their scope discrete WLAN and BT radio cards.

In some embodiments, the radio architecture 100 may include other radio cards, such as a cellular radio card configured for cellular (e.g., 3GPP such as LTE, LTE-Advanced or 5G communications).

In some IEEE 802.11 embodiments, the radio architecture 100 may be configured for communication over various channel bandwidths including bandwidths having center frequencies of about 900 MHz, 2.4 GHz, 5 GHz, and bandwidths of about 1 MHz, 2 MHz, 2.5 MHz, 4 MHz, 5 MHz, 8 MHz, 10 MHz, 16 MHz, 20 MHz, 40 MHz, 80 MHz (with contiguous bandwidths) or 80+80 MHz (160 MHz) (with non-contiguous bandwidths). In some embodiments, a 320 MHz channel bandwidth may be used. The scope of the embodiments is not limited with respect to the above center frequencies however.

FIG. 2 illustrates FEM circuitry 200 in accordance with some embodiments. The FEM circuitry 200 is one example of circuitry that may be suitable for use as the WLAN and/or BT FEM circuitry 104A/104B (FIG. 1), although other circuitry configurations may also be suitable.

In some embodiments, the FEM circuitry 200 may include a TX/RX switch 202 to switch between transmit mode and receive mode operation. The FEM circuitry 200 may include a receive signal path and a transmit signal path. The receive signal path of the FEM circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the circuitry 200 may include a power amplifier (PA) to amplify input RF signals 209 (e.g., provided by the radio IC circuitry 106), and one or more filters 212, such as band-pass filters (BPFs), low-pass filters (LPFs) or other types of filters, to generate RF signals 215 for subsequent transmission (e.g., by one or more of the antennas 101 (FIG. 1)).

In some dual-mode embodiments for Wi-Fi communication, the FEM circuitry 200 may be configured to operate in either the 2.4 GHz frequency spectrum or the 5 GHz frequency spectrum. In these embodiments, the receive signal path of the FEM circuitry 200 may include a receive signal path duplexer 204 to separate the signals from each spectrum as well as provide a separate LNA 206 for each spectrum as shown. In these embodiments, the transmit signal path of the FEM circuitry 200 may also include a power amplifier 210 and a filter 212, such as a BPF, a LPF or another type of filter for each frequency spectrum and a transmit signal path duplexer 214 to provide the signals of one of the different spectrums onto a single transmit path for subsequent transmission by the one or more of the antennas 101 (FIG. 1). In some embodiments, BT communications may utilize the 2.4 GHZ signal paths and may utilize the same FEM circuitry 200 as the one used for WLAN communications.

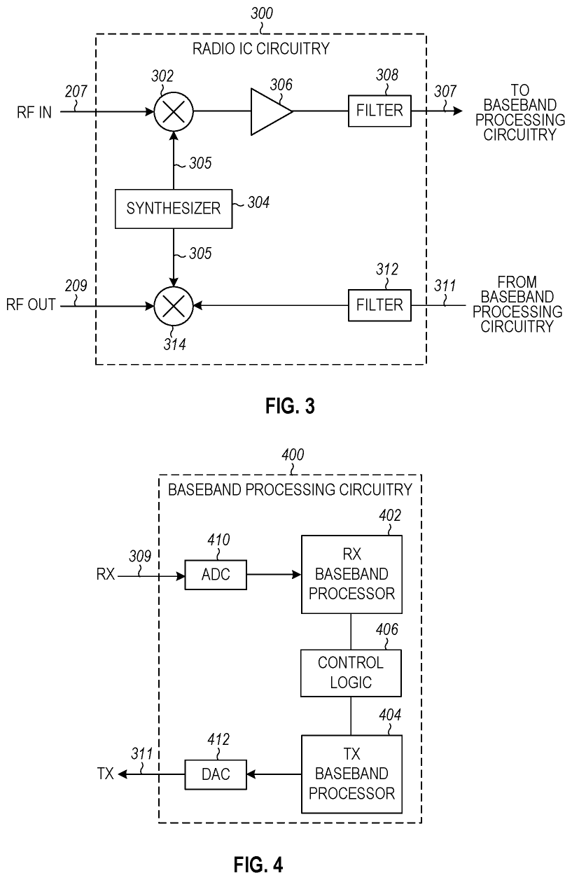

FIG. 3 illustrates radio IC circuitry 300 in accordance with some embodiments. The radio IC circuitry 300 is one example of circuitry that may be suitable for use as the WLAN or BT radio IC circuitry 106A/106B (FIG. 1), although other circuitry configurations may also be suitable.

In some embodiments, the radio IC circuitry 300 may include a receive signal path and a transmit signal path. The receive signal path of the radio IC circuitry 300 may include at least mixer circuitry 302, such as, for example, down-conversion mixer circuitry, amplifier circuitry 306 and filter circuitry 308. The transmit signal path of the radio IC circuitry 300 may include at least filter circuitry 312 and mixer circuitry 314, such as, for example, up-conversion mixer circuitry. Radio IC circuitry 300 may also include synthesizer circuitry 304 for synthesizing a frequency 305 for use by the mixer circuitry 302 and the mixer circuitry 314. The mixer circuitry 302 and/or 314 may each, according to some embodiments, be configured to provide direct conversion functionality. The latter type of circuitry presents a much simpler architecture as compared with standard super-heterodyne mixer circuitries, and any flicker noise brought about by the same may be alleviated for example through the use of OFDM modulation. FIG. 3 illustrates only a simplified version of a radio IC circuitry, and may include, although not shown, embodiments where each of the depicted circuitries may include more than one component. For instance, mixer circuitry 320 and/or 314 may each include one or more mixers, and filter circuitries 308 and/or 312 may each include one or more filters, such as one or more BPFs and/or LPFs according to application needs. For example, when mixer circuitries are of the direct-conversion type, they may each include two or more mixers.

In some embodiments, mixer circuitry 302 may be configured to down-convert RF signals 207 received from the FEM circuitry 104 (FIG. 1) based on the synthesized frequency 305 provided by synthesizer circuitry 304. The amplifier circuitry 306 may be configured to amplify the down-converted signals and the filter circuitry 308 may include a LPF configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 311 based on the synthesized frequency 305 provided by the synthesizer circuitry 304 to generate RF output signals 209 for the FEM circuitry 104. The baseband signals 311 may be provided by the baseband processing circuitry 108 and may be filtered by filter circuitry 312. The filter circuitry 312 may include a LPF or a BPF, although the scope of the embodiments is not limited in this respect.

In some embodiments, the mixer circuitry 302 and the mixer circuitry 314 may each include two or more mixers and may be arranged for quadrature down-conversion and/or up-conversion respectively with the help of synthesizer circuitry 304. In some embodiments, the mixer circuitry 302 and the mixer circuitry 314 may each include two or more mixers each configured for image rejection (e.g., Hartley image rejection). In some embodiments, the mixer circuitry 302 and the mixer circuitry 314 may be arranged for direct down-conversion and/or direct up-conversion, respectively. In some embodiments, the mixer circuitry 302 and the mixer circuitry 314 may be configured for super-heterodyne operation, although this is not a requirement.

Mixer circuitry 302 may comprise, according to one embodiment: quadrature passive mixers (e.g., for the in-phase (I) and quadrature phase (Q) paths). In such an embodiment, RF input signal 207 from FIG. 3 may be down-converted to provide I and Q baseband output signals to be sent to the baseband processor.

Quadrature passive mixers may be driven by zero and ninety-degree time-varying LO switching signals provided by a quadrature circuitry which may be configured to receive a LO frequency (f_{LO}) from a local oscillator or a synthesizer, such as LO frequency 305 of synthesizer circuitry 304 (FIG. 3). In some embodiments, the LO frequency may be the carrier frequency, while in other embodiments, the LO frequency may be a fraction of the carrier frequency (e.g., one-half the carrier frequency, one-third the carrier frequency). In some embodiments, the zero and ninety-degree time-varying switching signals may be generated by the synthesizer, although the scope of the embodiments is not limited in this respect.

In some embodiments, the LO signals may differ in duty cycle (the percentage of one period in which the LO signal is high) and/or offset (the difference between start points of the period). In some embodiments, the LO signals may have a 25% duty cycle and a 50% offset. In some embodiments, each branch of the mixer circuitry (e.g., the in-phase (I) and quadrature phase (Q) path) may operate at a 25% duty cycle, which may result in a significant reduction is power consumption.

The RF input signal 207 (FIG. 2) may comprise a balanced signal, although the scope of the embodiments is not limited in this respect. The I and Q baseband output signals may be provided to low-nose amplifier, such as amplifier circuitry 306 (FIG. 3) or to filter circuitry 308 (FIG. 3).

In some embodiments, the output baseband signals 307 and the input baseband signals 311 may be analog baseband signals, although the scope of the embodiments is not limited in this respect. In some alternate embodiments, the output baseband signals 307 and the input baseband signals 311 may be digital baseband signals. In these alternate embodiments, the radio IC circuitry may include analog-to-digital converter (ADC) and digital-to-analog converter (DAC) circuitry.

In some dual-mode embodiments, a separate radio IC circuitry may be provided for processing signals for each spectrum, or for other spectrums not mentioned here, although the scope of the embodiments is not limited in this respect.

In some embodiments, the synthesizer circuitry 304 may be a fractional-N synthesizer or a fractional N/N+1 synthesizer, although the scope of the embodiments is not limited in this respect as other types of frequency synthesizers may be suitable. For example, synthesizer circuitry 304 may be a delta-sigma synthesizer, a frequency multiplier, or a synthesizer comprising a phase-locked loop with a frequency divider. According to some embodiments, the synthesizer circuitry 304 may include digital synthesizer circuitry. An advantage of using a digital synthesizer circuitry is that, although it may still include some analog components, its footprint may be scaled down much more than the footprint of an analog synthesizer circuitry. In some embodiments, frequency input into synthesizer circuitry 304 may be provided by a voltage controlled oscillator (VCO), although that is not a requirement. A divider control input may further be provided by either the baseband processing circuitry 108 (FIG. 1) or application processor 111 (FIG. 1) depending on the desired output frequency 305. In some embodiments, a divider control input (e.g., N) may be determined from a look-up table (e.g., within a Wi-Fi card) based on a channel number and a channel center frequency as determined or indicated by application processor 111.

In some embodiments, synthesizer circuitry 304 may be configured to generate a carrier frequency as the output frequency 305, while in other embodiments, the output frequency 305 may be a fraction of the carrier frequency (e.g., one-half the carrier frequency, one-third the carrier frequency). In some embodiments, the output frequency 305 may be a LO frequency (f_{LO}).

FIG. 4 illustrates a functional block diagram of baseband processing circuitry 400 in accordance with some embodiments. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 309 provided by the radio IC circuitry 106 (FIG. 1) and a transmit baseband processor (TX BBP) 404 for generating transmit baseband signals 311 for the radio IC circuitry 106. The baseband processing circuitry 400 may also include control logic 406 for coordinating the operations of the baseband processing circuitry 400.

In some embodiments (e.g., when analog baseband signals are exchanged between the baseband processing circuitry 400 and the radio IC circuitry 106), the baseband processing circuitry 400 may include ADC 410 to convert analog baseband signals received from the radio IC circuitry 106 to digital baseband signals for processing by the RX BBP 402. In these embodiments, the baseband processing circuitry 400 may also include DAC 412 to convert digital baseband signals from the TX BBP 404 to analog baseband signals.

In some embodiments that communicate OFDM signals or OFDMA signals, such as through baseband processor 108A, the transmit baseband processor 404 may be configured to generate OFDM or OFDMA signals as appropriate for transmission by performing an inverse fast Fourier transform (IFFT). The receive baseband processor 402 may be configured to process received OFDM signals or OFDMA signals by performing an FFT. In some embodiments, the receive baseband processor 402 may be configured to detect the presence of an OFDM signal or OFDMA signal by performing an autocorrelation, to detect a preamble, such as a short preamble, and by performing a cross-correlation, to detect a long preamble. The preambles may be part of a predetermined frame structure for Wi-Fi communication.

Referring back to FIG. 1, in some embodiments, the antennas 101 (FIG. 1) may each comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result. Antennas 101 may each include a set of phased-array antennas, although embodiments are not so limited.

Although the radio architecture 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

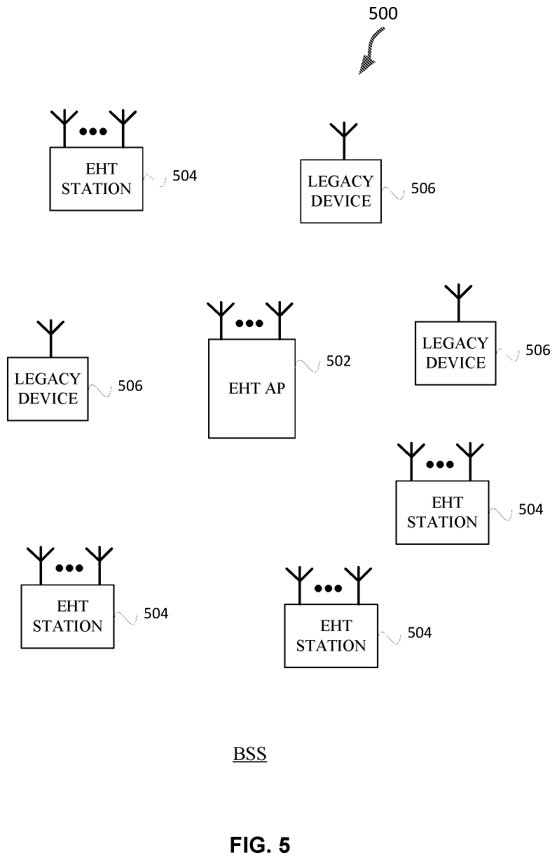

FIG. 5 illustrates a WLAN 500 in accordance with some embodiments. The WLAN 500 may comprise a basis service set (BSS) that may include an access point (AP) 502, which may be an AP, a plurality of stations 504, and a plurality of legacy (e.g., IEEE 802.11n/ac/ax) devices 506. In some embodiments, WLAN 500 may be configured for Extremely High Throughput (EHT) communications in accordance with the IEEE 802.11be standard and one or more stations including AP 502 and stations 504 may be EHT STAs. In some embodiments, WLAN 500 may be configured for Ultra-High Rate (UHR) communications in accordance with one of the IEEE 802.11 standards or draft standards and one or more stations including AP 502 and stations 504 may be UHR and/or UHR+STAs.

In some embodiments, WLAN 500 may be configured for next generation vehicle-to-everything (NGV) communications in accordance with the IEEE 802.11bd standard and one or more stations including AP 502 may be next generation vehicle-to-everything (NGV) stations (STAs).

The AP 502 may be an AP using the IEEE 802.11 to transmit and receive. The AP 502 may be a base station. The AP 502 may use other communications protocols as well as the IEEE 802.11 protocol. The IEEE 802.11 protocol may be IEEE 802.11ax. The IEEE 802.11 protocol may include using orthogonal frequency division multiple-access (OFDMA), time division multiple access (TDMA), and/or code division multiple access (CDMA). The IEEE 802.11 protocol may include a multiple access technique. For example, the IEEE 802.11 protocol may include space-division multiple access (SDMA) and/or multiple-user multiple-input multiple-output (MU-MIMO). There may be more than one AP 502 that is part of an extended service set (ESS). A controller (not illustrated) may store information that is common to the more than one APs 502.

The legacy devices 506 may operate in accordance with one or more of IEEE 802.11 a/b/g/n/ac/ad/af/ah/aj/ay, or another legacy wireless communication standard. The legacy devices 506 may be STAs or IEEE STAs. The STAs 504 may be wireless transmit and receive devices such as cellular telephone, portable electronic wireless communication devices, smart telephone, handheld wireless device, wireless glasses, wireless watch, wireless personal device, tablet, or another device that may be transmitting and receiving using the IEEE 802.11 protocol such as IEEE 802.11ax or another wireless protocol. In some embodiments, the STAs 504 may be termed high efficiency (HE) stations.

AP 502 may communicate with legacy devices 506 in accordance with legacy IEEE 802.11 communication techniques. In example embodiments, AP 502 may also be configured to communicate with STAs 504 in accordance with legacy IEEE 802.11 communication techniques.

In some embodiments, a frame may be configurable to have the same bandwidth as a channel. The frame may be a physical Layer Convergence Procedure (PLCP) Protocol Data Unit (PPDU). In some embodiments, there may be several types of PPDUs that may have different fields and different physical layers and/or different media access control (MAC) layers.

The bandwidth of a channel may be 20 MHz, 40 MHz, or 80 MHz, 160 MHz, 320 MHz contiguous bandwidths or an 80+80 MHz (160 MHz) non-contiguous bandwidth. In some embodiments, the bandwidth of a channel may be 1 MHz, 1.25 MHz, 2.03 MHz, 2.5 MHz, 4.06 MHz, 5 MHz and 10 MHz, or a combination thereof or another bandwidth that is less or equal to the available bandwidth may also be used. In some embodiments the bandwidth of the channels may be based on a number of active data subcarriers. In some embodiments the bandwidth of the channels is based on 26, 52, 106, 242, 484, 996, or 2×996 active data subcarriers or tones that are spaced by 20 MHz. In some embodiments the bandwidth of the channels is 256 tones spaced by 20 MHz. In some embodiments the channels are multiple of 26 tones or a multiple of 20 MHz. In some embodiments a 20 MHz channel may comprise 242 active data subcarriers or tones, which may determine the size of a Fast Fourier Transform (FFT). An allocation of a bandwidth or a number of tones or sub-carriers may be termed a resource unit (RU) allocation in accordance with some embodiments.

In some embodiments, the 26-subcarrier RU and 52-subcarrier RU are used in the 20 MHz, 40 MHz, 80 MHz, 160 MHz and 80+80 MHz OFDMA PPDU formats. In some embodiments, the 106-subcarrier RU is used in the 20 MHz, 40 MHz, 80 MHz, 160 MHz and 80+80 MHz OFDMA and MU-MIMO PPDU formats. In some embodiments, the 242-subcarrier RU is used in the 40 MHz, 80 MHz, 160 MHz and 80+80 MHz OFDMA and MU-MIMO PPDU formats. In some embodiments, the 484-subcarrier RU is used in the 80 MHz, 160 MHz and 80+80 MHz OFDMA and MU-MIMO PPDU formats. In some embodiments, the 996-subcarrier RU is used in the 160 MHz and 80+80 MHz OFDMA and MU-MIMO PPDU formats.

A frame may be configured for transmitting a number of spatial streams, which may be in accordance with MU-MIMO and may be in accordance with OFDMA. In other embodiments, AP 502, STA 504, and/or legacy device 506 may also implement different technologies such as code division multiple access (CDMA) 2000, CDMA 2000 1×, CDMA 2000 Evolution-Data Optimized (EV-DO), Interim Standard 2000 (IS-2000), Interim Standard 95 (IS-95), Interim Standard 856 (IS-856), Long Term Evolution (LTE), Global System for Mobile communications (GSM), Enhanced Data rates for GSM Evolution (EDGE), GSM EDGE (GERAN), IEEE 802.16 (i.e., Worldwide Interoperability for Microwave Access (WiMAX)), BlueTooth®, or other technologies.

Some embodiments relate to HE and/or EHT communications. In accordance with some IEEE 802.11 embodiments (e.g., IEEE 802.11ax embodiments) a AP 502 may operate as a primary station which may be arranged to contend for a wireless medium (e.g., during a contention period) to receive exclusive control of the medium for an control period. In some embodiments, the control period may be termed a transmission opportunity (TXOP). AP 502 may transmit a master-sync transmission, which may be a trigger frame or control and schedule transmission, at the beginning of the control period. AP 502 may transmit a time duration of TXOP and sub-channel information. During the control period, STAs 504 may communicate with AP 502 in accordance with a non-contention based multiple access technique such as OFDMA or MU-MIMO. This is unlike conventional WLAN communications in which devices communicate in accordance with a contention-based communication technique, rather than a multiple access technique. During the control period, the AP 502 may communicate with STAs 504 using one or more frames. During the control period, the STAs 504 may operate on a sub-channel smaller than the operating range of the AP 502. During the control period, legacy stations refrain from communicating. The legacy stations may need to receive the communication from the AP 502 to defer from communicating.

In accordance with some embodiments, during TXOP the STAs 504 may contend for the wireless medium with the legacy devices 506 being excluded from contending for the wireless medium during the master-sync transmission. In some embodiments the trigger frame may indicate an uplink (UL) and/or UL OFDMA TXOP. In some embodiments, the trigger frame may include a DL UL-MU-MIMO and/or DL OFDMA with a schedule indicated in a preamble portion of trigger frame.

In some embodiments, the multiple-access technique used during the TXOP may be a scheduled OFDMA technique, although this is not a requirement. In some embodiments, the multiple access technique may be a time-division multiple access (TDMA) technique or a frequency division multiple access (FDMA) technique. In some embodiments, the multiple access technique may be a space-division multiple access (SDMA) technique. In some embodiments, the multiple access technique may be a Code division multiple access (CDMA).

The AP 502 may also communicate with legacy devices 506 and/or non-legacy stations 504 in accordance with legacy IEEE 802.11 communication techniques. In some embodiments, the AP 502 may also be configurable to communicate with STAs 504 outside the TXOP in accordance with legacy IEEE 802.11 communication techniques, although this is not a requirement. Some embodiments are directed to an apparatus of a STA configured for operation in a WLAN comprising processing circuitry and memory. Some embodiments are directed to a non-transitory computer-readable storage medium that stores instructions for execution by processing circuitry. In some embodiments station 504 may be a “group owner” (GO) for peer-to-peer modes of operation. A wireless device may be a station 504 or a AP 502.

In some embodiments, the station 504 and/or AP 502 may be configured to operate in accordance with IEEE 802.11mc. In example embodiments, the radio architecture of FIG. 1 is configured to implement the station 504 and/or the AP 502. In example embodiments, the front-end module circuitry of FIG. 2 is configured to implement the station 504 and/or the AP 502. In example embodiments, the radio IC circuitry of FIG. 3 is configured to implement the station 504 and/or the AP 502. In example embodiments, the base-band processing circuitry of FIG. 4 is configured to implement the station 504 and/or the AP 502.

In example embodiments, the Stations 504, AP 502, an apparatus of the Stations 504, and/or an apparatus of the AP 502 may include one or more of the following: the radio architecture of FIG. 1, the front-end module circuitry of FIG. 2, the radio IC circuitry of FIG. 3, and/or the base-band processing circuitry of FIG. 4.

In example embodiments, the radio architecture of FIG. 1, the front-end module circuitry of FIG. 2, the radio IC circuitry of FIG. 3, and/or the base-band processing circuitry of FIG. 4 may be configured to perform the methods and operations/functions herein.

In example embodiments, the station 504 and/or the AP 502 are configured to perform the methods and operations/functions described herein. In example embodiments, an apparatus of the station 504 and/or an apparatus of the AP 502 are configured to perform the methods and functions described herein. The term Wi-Fi may refer to one or more of the IEEE 802.11 communication standards. AP and STA may refer to access point 502 and/or station 504 as well as legacy devices 506.

In some embodiments, the AP and STAs may communicate in accordance with one of the IEEE 802.11 standards. IEEE Std 802.11-2020, IEEE P802.11ax/D8.0, October 2020, IEEE P802.11REVmd/D5.0, IEEE P802.11be/D3.0, January 2023 and IEEE P802.11-REVme/D1.3 are incorporated herein by reference in their entireties.

Probabilistic constellation shaping can provide about 1 dB gain or more for higher order QAM levels in WLANs. However, when a decoding error occurs, the error not only flips some bits but may also insert or delete some bits. This causes a problem for the bit descrambling at the receiver. Namely, the descrambling sequence and the decoded bit sequence lose synchronization after the error occurs.

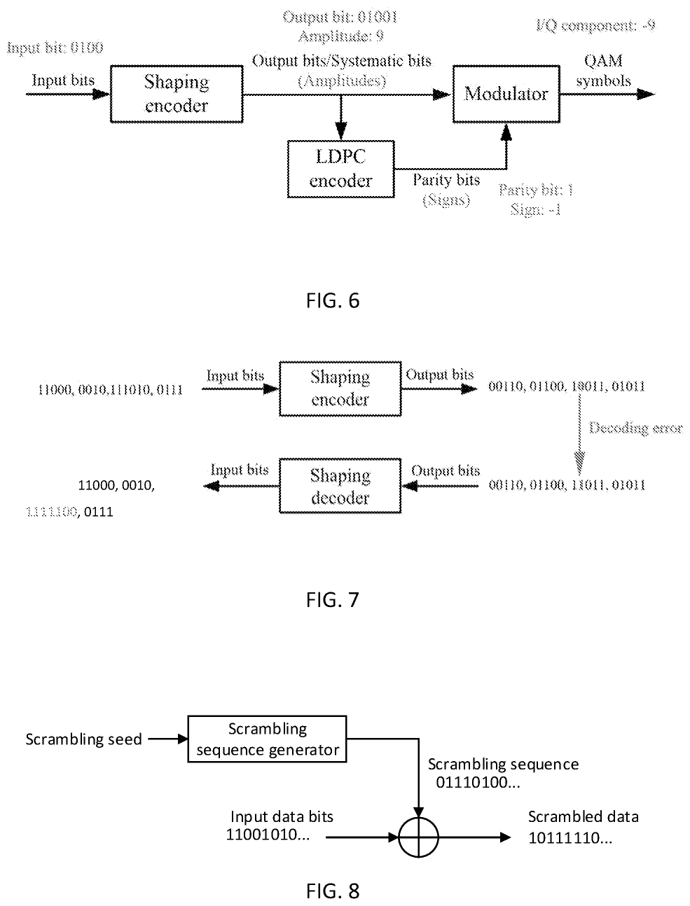

FIG. 6 illustrates probabilistic constellation shaping, in accordance with some embodiments. The input bits are first encoded by the shaping encoder, whose example is shown in Table 1. Bit segments with different lengths are converted into bit tuples of a fixed length (e.g., 5 bits for 4K-QAM and 4 bits for 1K-QAM). Each bit tuple specifies (or is mapped to) an amplitude of the I or Q component of the QAM constellation at the QAM modulator. For protecting these amplitude bits, an FEC encoder (e.g., LDPC) may be employed. The FEC encoder takes the bit tuples as its input and generates parity bits as its output. The generated parity bits are used as the sign bits by the QAM modulator. For example, amplitude bit tuple 01111 is mapped to amplitude 1, and sign bit 0 assigns a positive polarity to the amplitude such that these six bits 011110 are represented by +1 in an I or Q component of 4K-QAM constellation.

TABLE 1
Shaping encoder for 4K-QAM.

| Input bits | Amplitude | Probability | Output bits |
|---|---|---|---|
| 0000 | 1 | 1/16 | 01111 |
| 0001 | 3 | 1/16 | 01110 |
| 0010 | 5 | 1/16 | 01100 |
| 0011 | 7 | 1/16 | 01101 |
| 0100 | 9 | 1/16 | 01001 |
| 0101 | 11 | 1/16 | 01000 |
| 0110 | 13 | 1/16 | 01010 |
| 0111 | 15 | 1/16 | 01011 |
| 1000 | 17 | 1/16 | 00011 |
| 1001 | 19 | 1/16 | 00010 |
| 10100 | 21 | 1/32 | 00000 |
| 10101 | 23 | 1/32 | 00001 |
| 10110 | 25 | 1/32 | 00101 |
| 10111 | 27 | 1/32 | 00100 |
| 11000 | 29 | 1/32 | 00110 |
| 11001 | 31 | 1/32 | 00111 |
| 11010 | 33 | 1/32 | 10111 |
| 11011 | 35 | 1/32 | 10110 |
| 111000 | 37 | 1/64 | 10100 |
| 111001 | 39 | 1/64 | 10101 |
| 111010 | 41 | 1/64 | 10001 |
| 111011 | 43 | 1/64 | 10000 |
| 111100 | 45 | 1/64 | 10010 |
| 111101 | 47 | 1/64 | 10011 |
| 1111100 | 49 | 1/128 | 11011 |
| 1111101 | 51 | 1/128 | 11010 |
| 1111110 | 53 | 1/128 | 11000 |
| 11111110 | 55 | 1/256 | 11001 |
| 111111110 | 57 | 1/512 | 11101 |
| 111111111 | 59 | 1/512 | 11100 |
| — | 61 | 0 | — |
| — | 63 | 0 | — |

FIG. 7 illustrates bit shift due to a decoding error, in accordance with some embodiments. The bit error results into a wrong amplitude, and the wrong amplitude is further decoded as a wrong bit segment, which may have a length different from the correct one. The bit shift causes a byte boundary shift which increases the search complexity in locating the MPDU delimiter.

FIG. 8 illustrates the scrambling of input data bits, in accordance with some embodiments. The input bits in FIG. 7 are the scrambled data bits in FIG. 8. The scrambling sequence in FIG. 8 is added to the input data bits bit by bit. At the receiver, a reverse processing called descrambling is conducted to remove the scrambling sequence for retrieving the input data bits. Namely, the receiver generates the same scrambling sequence by using the same scrambling sequence generator and the same scrambling seed and adding the generated sequence to the decoded bits delivered by the shaping decoder. The descrambling process assumes a perfect synchronization between the decoded bits and the scrambling sequence. However, because of the bit shift in the decoded bits due to decoding errors, the synchronization is lost.

The bit shift causes the byte boundary shift. Embodiments disclosed herein provide a way to resynchronize the scrambling sequence with the decoded bits after error occurs.

Scheme 1—No Scrambling

In these embodiments, the scrambling of input data is disabled for probabilistic constellation shaping. The scrambling is intended to change the PAPR of the transmitted signal in the retransmission. Without the scrambling, the transmitter can still change the PAPR. For example, the transmitter can permute the order of the MPDUs within the A-MPDU for the retransmission for changing the output of the shaping encoder. For another example, the transmitter can add a null MPDU (i.e., a MPDU delimiter) at the beginning of the retransmission for changing the output of the shaping encoder.

Scheme 2—Scramble Only Data Bits

In these embodiments, to address the byte boundary shift, two blocks are defined, one for input data bits into the shaping encoder and the other for the output bits out of the shaping encoder. Each output bit block is associated with an input data block. The length of the output bit block is known to the receiver. The corresponding length of the input data block is variable and unknown to the receiver. The input data block consists of valid input data bits and padding bits. The number of valid input data bits in the input data block is known to the receiver and is equal or less than the length of the input data block. Padding bits with variable lengths are usually appended to the valid input data bits for filling up the input data block. The padding bits can be changed for each retransmission so that the PAPR changes.

In these embodiments, only the valid input data bits are scrambled and not the padding bits. For example, the 1^{st} input data block has 1000 valid input data bits and 19 padding bits; the 2^{nd} input data block has 1000 valid input data bits and 2 padding bits. The first 1000 bits of the scrambling sequence are applied to the 1000 valid input data bits of the first input data block and the second 1000 bits of the scrambling sequence are applied to the 1000 valid input data bits of the second input data block. No scrambling is applied to the padding bits in the input data blocks. It should be noticed that each input data block consumes 1000 scrambling bits, each of which is added to one valid input data bit. No matter whether decoding errors occur or not, the receiver always applies 1000 scrambling bits to the first 1000 decoded bits per data block for descrambling the first 1000 data bits, which are assumed to be the valid input data bits. The descrambled bits are then reported as the received data bits. The number of scrambling bits and the number of the valid input data bits always match block by block. Since the number of valid input data bits for each output bit block and the number of output bit blocks are known to the receiver, the receiver can resynchronize the descrambling sequence with the input data bits at the beginning of each input data block even though error may occur.

As an alternative, the scrambling sequence generator may get restarted for each input data block. The restart of the scrambling sequence generator is the same as the initial start. The generator initializes its state (i.e., the registers) using a scrambling seed known to the receiver. After initialization, the generator starts to generate a scrambling sequence that is added to the decoded valid input data. If the scrambling seed remains the same for each input data block, then the same scrambling sequence is generated for each input data block. The initial scrambling seed is sent at the beginning of each PPDU's data field without scrambling so that the receiver can read it. The scrambling seed may vary from block to block. A new scrambling seed may be sent without scrambling at the beginning of each block. Or, for reducing the overhead, only the scrambling seed of the first block is explicitly sent by the transmitter and the scrambling seeds of the latter blocks can be generated from the first scrambling seed. For example, the scrambling seed of block m may be given by the following equation:

sₘ=mod(sₘ₋₁+c₀,c₁)+c₂,
where sₘ₋₁ is the scrambling seed of block m−1; c₀ is a constant integer; c₁ is another constant integer (e.g., 128) determined by the constraint length of the scrambling sequence generator; c₂ is a third constant integer.

Scheme 3—Restart Scrambler Per Tag

In these embodiments, to address the byte boundary shift a tag (or mark) may be inserted into the output or input of the shaping encoder. The tag is inserted for every K bits of input data or payload data, where K is a number known to the receiver (e.g., 1000 bytes). For example, the tag may be represented by amplitude 63 or 70, which is inserted into the output amplitude sequence of the shaping encoder for 4K-QAM. Once the receiver detects the tag, it knows there are 1000 bytes of input data between the two tags just detected. Once error occurs, some tag may be corrupted and missed such that the receiver doesn't know how many data bits has been input before the next tag correctly detected.

If the tag indicates that how many bits has been input (e.g., 12′K bits), then there is no need to change the existing scrambling and descrambling processes. If the tag only indicates a multiple of K bits instead of the exact number of bits (or the exact value of the multiple), then the receiver may not be able to figure out what the multiple exactly is when the receiver detects a tag after error occurred. If the K is a large number (e.g., 8000), the receiver may be able to estimate the multiple with high reliability at the cost of complexity. In this case, there may be no need to change the existing scrambling and descrambling processes. If the receiver doesn't want to increase the complexity to estimate the multiple or the K is not a large number, the scrambling sequence generator may be restarted for every K bits at the transmitter so that the receiver knows exactly the scrambling sequence after each tag is correctly detected. Namely, after the transmitter sends K bits of input data and an unscrambled tag, the transmitter restarts the scrambling sequence generator for the next K bits of input data. As a result, after error occurs, the scrambling sequence gets resynchronized after a tag is correctly detected.

The restart of the scrambling sequence generator is the same as the initial start. The generator initializes its state (i.e., the registers) using a scrambling seed known to the receiver. After initialization, the generator starts to generate a scrambling sequence to be added to the input data bits. The initial scrambling seed is sent at the beginning of PPDU's data field without scrambling so that the receiver can read it. This initial scrambling seed can be used again for each restart. Or, a new scrambling seed may be sent without scrambling, after or before the tag, for the restart after the tag. Or, for reducing overhead, only the scrambling seed of the first input data block, which ends right before the first tag, is explicitly sent by the transmitter and the scrambling seeds of the latter blocks, each of which consists of input data bits between two adjacent tags, can be generated from the first scrambling seed. For example, the scrambling seed of block m may be given by the following equation:

sₘ=mod(sₘ₋₁+c₀,c₁)+c₂,
where sₘ₋₁ is the scrambling seed of block m−1; c₀ is a constant integer; c₁ is another constant integer (e.g., 128) determined by the constraint length of the scrambling sequence generator; c₂ is a third constant integer.

Scheme 4—Restart Scrambler Per Block

In these embodiments, to address the byte boundary shift, a restriction may be applied to the number of valid input data bits for each output bit block. Specifically, the number of valid input data bits needs be a multiple of 32 bits for each input data block and each corresponding output bit block. The sizes of the output bit block are known the receiver. In these embodiments, the scrambling sequence generator may be restarted per input data block. The reason is that the number of valid input bits per block is variable. In the case of decoding error, the receiver doesn't know how many scrambling bits should be used for a corrupted block and which scrambling bit in the scrambling sequence should be the first scrambling bit for the next block.

The restart of the scrambling sequence generator is the same as the initial start. The generator initializes its state (i.e., the registers) using a scrambling seed known to the receiver. After initialization, the generator starts to generate a scrambling sequence to be added to the input data. The initial scrambling seed is sent at the beginning of PPDU's data field without scrambling so that the receiver can read it. This initial scrambling seed can be used again for each restart. Alternatively, a new scrambling seed may be sent without scrambling right before each input data block (or the corresponding output bit block) for restarting the scrambling sequence generator. Or, for reducing overhead, only the scrambling seed of the first block is explicitly sent by the transmitter and the scrambling seeds of the latter blocks can be generated from the first scrambling seed. For example, the scrambling seed of block m may be given by the following equation:

sₘ=mod(sₘ₋₁+c₀,c₁)+c₂,
where sₘ₋₁ is the scrambling seed of block m−1; c₀ is a constant integer; c₁ is another constant integer (e.g., 128) determined by the constraint length of the scrambling sequence generator; c₂ is a third constant integer.

Scheme 5—Restart Scrambler Per MPDU

In these embodiments, to address the byte boundary shift, the transmitter may restart the scrambling sequence generator per MPDU, since for an A-MPDU, the receiver needs to detect the MPDU delimiter anyway. For the receiver to identify the MPDU delimiter, the MPDU delimiter may not be scrambled. After each MPDU delimiter, the scrambling sequence generator may be restarted. Because the receiver doesn't know how many MPDUs were transmitted when error occurs, the scrambling seed remains the same for all MPDUs within the A-MPDU.

The restart of the scrambling sequence generator is the same as the initial start. The generator initializes its state (i.e., the registers) using a scrambling seed known to the receiver. After initialization, the generator starts to generate a scrambling sequence to be added to the input data. The initial scrambling seed is sent at the beginning of PPDU's data field without scrambling so that the receiver can read it. This initial scrambling seed can be used again for each restart. Alternatively, a new scrambling seed may be sent without scrambling right before each MPDU (or the corresponding output bit block) for restarting the scrambling sequence generator. Or, for reducing overhead, only the scrambling seed of the first MPDU is explicitly sent by the transmitter and the scrambling seeds of the latter MPDU can be generated from the first scrambling seed. For example, the scrambling seed of MPDU m may be given by the following equation:

sₘ=mod(sₘ₋₁+c₀,c₁)+c₂,
where sₘ₋₁ is the scrambling seed of MPDU m−1; c₀ is a constant integer; c₁ is another constant integer (e.g., 128) determined by the constraint length of the scrambling sequence generator; c₂ is a third constant integer.

Some embodiments are directed to a station (STA) configured for operation in a WLAN. In these embodiments, the STA may perform bit scrambling on input bits to generate scrambled input bits and may perform probabilistic constellation shaping using a shaping encoder on the scrambled input bits. In these embodiments, the shaping encoder may encode a segment of the scrambled input bits for a modulation order and generate a shaped bit stream. In these embodiments, the STA may generate a QAM symbol stream with a first QAM modulator. The QAM symbol stream may be generated at least from the shaped bit stream and from parity bits using the modulation order. In these embodiments, the STA may generate the parity bits from the shaped bit streams with a forward-error correction (FEC) encoder and may transmit the QAM symbol stream within a physical layer protocol data unit (PPDU). In these embodiments, to address a potential byte boundary shift caused a decoding error at a receiving station, the STA may modify performance of the bit scrambling when probabilistic constellation shaping is performed. In these embodiments, bit scrambling may help reduce the PAPR of the transmitted signal.

In some embodiments, to address the byte boundary shift, the STA may refrain from performing the bit scrambling when the probabilistic constellation shaping is performed. In these embodiments, the STA may modify a peak-to-average power ratio (PAPR) at transmission of the QAM symbol stream to at least in part compensate for a PAPR change resulting from the refraining from performing of the bit scrambling. In these embodiments, the PAPR of the transmitted signal that comprises of the QAM symbol stream may be decreased (e.g., by permuting the order of MPDUs within an A-MPDU) to at least in part compensate for a PAPR increase resulting from the refraining from performing of the bit scrambling.

In some embodiments, the input bits for the bit scrambling comprise a variable length input data block comprising a variable number of padding bits and a fixed number of valid input bits. In these embodiments, In some embodiments, to address the byte boundary shift, the STA may perform scrambling on the valid input bits and may refrain from performing bit scrambling on the padding bits to provide output bit blocks to the shaping encoder. In these embodiments, the receiving STA may know the number of valid input bits.

In these embodiments, the STA may restart (i.e., initialize) a scrambling sequence generator for each variable length input data block for performance of the bit scrambling. In these embodiments, when a scrambling seed that is not known to the receiving station is used for restarting the scrambling sequence generator, the STA may send the scrambling seed to the receiving station at a beginning of a data field of the PPDU.

In some embodiments, to address the byte boundary shift, the STA may insert a tag into the scrambled input bits before performance of the probabilistic constellation shaping. In these embodiments, the tag may indicate a number of bits that have been scrambled. In these embodiments, the STA may restart (i.e., initialize) a scrambling sequence generator for performance of the bit scrambling at each tag so that the receiver knows exactly the scrambling sequence after each tag is correctly detected. In these embodiments, when a scrambling seed that is not known to the receiving station is used for restarting the scrambling sequence generator, the STA may send the scrambling seed to the receiving station at a beginning of a data field of the PPDU.

In some embodiments, the input bits for the bit scrambling comprise a variable length input data block. In some embodiments, to address the byte boundary shift, the STA may restrict a number of valid input data bits for the performance of the bit scrambling for each output bit block to a predetermined number (e.g., multiples of 32 bits) and may restart (i.e., initialize) a scrambling sequence generator for performance of the bit scrambling for each input data block. In these embodiments, when a scrambling seed that is not known to the receiving station is used for restarting the scrambling sequence generator, the STA may send the scrambling seed to the receiving station without scrambling before each input data block.

In some embodiments, the PPDU may comprise an aggregated MAC protocol data unit (A-MPDU) comprising a plurality of MPDUs and one or more MPDU delimiters. In these embodiments, to address the byte boundary shift, the STA may restart a scrambling sequence generator for performance of the bit scrambling after each of the MPDU delimiters using a same scrambling seed for each of the MPDUs of the A-MPDU. In these embodiments, when a scrambling seed that is not known to the receiving station is used for restarting the scrambling sequence generator, the STA may send the scrambling seed to the receiving station before each MPDU. In these embodiments, because the receiver doesn't know how many MPDUs were transmitted when a byte boundary shift error occurs, the scrambling seed remains the same for all MPDUs within the A-MPDU.

In some embodiments, for probabilistic constellation shaping, the shaping encoder may determine amplitude bit tuples of a fixed length for the shaped bit stream by matching segments of the scrambled input bits of different lengths with table entries of a constellation shaping table for the modulation order. In these embodiments, the potential byte boundary shift may be caused a decoding error at the receiving station resulting in an incorrect length for one or more of the segments of the input bits. In some embodiments, when the modulation order is 4K-QAM, the fixed length for the amplitude bit tuples is five bits. In some embodiments, when the modulation order is 1K-QAM, the fixed length for the amplitude bit tuples is four bits.

In these embodiments, constellation shaping may:
Increase throughput: By shaping the constellation to favor certain signal points over others, more information can be transmitted per modulation symbol while maintaining the same average power. This improves spectral efficiency.
Improve resilience: Constellation shaping creates a non-uniform distribution of points that maximizes the minimum Euclidean distance between points. This improves resilience to noise and interference.
Reduce peak-to-average power ratio (PAPR): Shaping can minimize long sequences of high power signals, lowering PAPR in OFDM systems. This improves power amplifier efficiency.
Adapt to channel conditions: The probabilistic distribution can be optimized based on channel conditions. For good channels, throughput is maximized. For poor channels, resilience is maximized.

In these embodiments, performing bit scrambling may:
Reduce electromagnetic interference (EMI): Scrambling helps randomize the data being transmitted, spreading the energy more evenly across the frequency band and reducing peaks that could cause EMI. This allows the WLAN to better coexist with other electronic devices.
Improve power amplifier efficiency: Scrambling can help avoid long strings of 1s or 0s in the transmitted data, which reduces the peak-to-average power ratio. This allows the power amplifiers to operate more efficiently and with less distortion.
Enhance security: Scrambling makes data more random, making it more difficult for an eavesdropper to reconstruct the original data stream. This adds an extra layer of security.
Assist clock recovery: The scrambler adds transitions to the transmitted signal that the receiver can use to recover the clock and timing information. This helps the receiver synchronize to the signal.
Overcome weak signal issues: Scrambling reduces the probability of long strings of 0s or 1s which could cause loss of signal when transmitted over a weak channel. The added randomness makes the signal more robust.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus of a station (STA) configured for operation in a WLAN, the apparatus comprising processing circuitry; and memory, the processing circuitry to:
perform bit scrambling on input bits to generate scrambled input bits;
perform probabilistic constellation shaping using a shaping encoder on the scrambled input bits, the shaping encoder configured to encode a segment of the scrambled input bits for a modulation order and generate a shaped bit stream,
generate a QAM symbol stream with a QAM modulator, the QAM symbol stream generated at least from the shaped bit stream and from parity bits using the modulation order;
generate the parity bits from the shaped bit streams with a forward-error correction (FEC) encoder; and
cause the STA to transmit the QAM symbol stream within a physical layer protocol data unit (PPDU),
wherein to address a byte boundary shift at a receiving station, the processing circuitry is configured to modify performance of the bit scrambling when probabilistic constellation shaping is performed.

2. The apparatus of claim 1, wherein for the probabilistic constellation shaping the shaping encoder determines amplitude bit tuples of a fixed length for the shaped bit stream by matching segments of the input bits of different lengths with table entries of a constellation shaping table for the modulation order,
wherein the byte boundary shift is caused a decoding error at the receiving station resulting in an incorrect length for one or more of the segments of the input bits.

3. The apparatus of claim 2, wherein to address the byte boundary shift, the processing circuitry is to:
refrain from performing the bit scrambling when the probabilistic constellation shaping is performed; and
modify a peak-to-average power ratio (PAPR) at transmission of the QAM symbol stream to at least in part compensate for a PAPR change resulting from the refraining from performing of the bit scrambling.

4. The apparatus of claim 2, wherein the input bits for the bit scrambling comprise a variable length input data block comprising a variable number of padding bits and a fixed number of valid input bits,
wherein to address the byte boundary shift, the processing circuitry is to:
perform scrambling on the valid input bits and refrain from performing bit scrambling on the padding bits to provide output bit blocks to the shaping encoder.

5. The apparatus of claim 4, wherein the processing circuitry is to restart a scrambling sequence generator for each input data block for performance of the bit scrambling,
wherein when a scrambling seed that is not known to the receiving station is used for restarting the scrambling sequence generator, the processing circuitry is configured to send the scrambling seed to the receiving station at a beginning of a data field of the PPDU.

6. The apparatus of claim 2, wherein to address the byte boundary shift, the processing circuitry is to:
insert a tag into the scrambled input bits before performance of the probabilistic constellation shaping, the tag indicating a number of bits; and
restart a scrambling sequence generator for performance of the bit scrambling at each tag,
wherein when a scrambling seed that is not known to the receiving station is used for restarting the scrambling sequence generator, the processing circuitry is configured to send the scrambling seed to the receiving station at a beginning of a data field of the PPDU.

7. The apparatus of claim 2, wherein the input bits for the bit scrambling comprise a variable length input data block, and
wherein to address the byte boundary shift, the processing circuitry is to:
restrict a number of valid input data bits for the performance of the bit scrambling for each output bit block to a predetermined number; and
restart a scrambling sequence generator for performance of the bit scrambling for each input data block,
wherein when a scrambling seed that is not known to the receiving station is used for restarting the scrambling sequence generator, the processing circuitry is configured to send the scrambling seed to the receiving station without scrambling before each input data block.

8. The apparatus of claim 2, wherein the PPDU comprises an aggregated MAC protocol data unit (A-MPDU) comprising a plurality of MPDUs and one or more MPDU delimiters,
wherein to address the byte boundary shift, the processing circuitry is to:
restart a scrambling sequence generator for performance of the bit scrambling after each of the MPDU delimiters using a same scrambling seed for each of the MPDUs of the A-MPDU,
wherein when a scrambling seed that is not known to the receiving station is used for restarting the scrambling sequence generator, the processing circuitry is configured to send the scrambling seed to the receiving station before each MPDU.

9. The apparatus of claim 2, wherein when the modulation order is 4K-QAM, the fixed length for the amplitude bit tuples is five bits, and
wherein when the modulation order is 1K-QAM, the fixed length for the amplitude bit tuples is four bits.

10. The apparatus of claim 9, wherein the STA is a ultra-high rate (UHR) station.

11. A non-transitory computer-readable storage medium that stores instructions for execution by processing circuitry of a station (STA) configured for operation in a WLAN, the processing circuitry to:
perform bit scrambling on input bits to generate scrambled input bits;
perform probabilistic constellation shaping using a shaping encoder on the scrambled input bits, the shaping encoder configured to encode a segment of the scrambled input bits for a modulation order and generate a shaped bit stream,
generate a QAM symbol stream with a QAM modulator, the QAM symbol stream generated at least from the shaped bit stream and from parity bits using the modulation order;
generate the parity bits from the shaped bit streams with a forward-error correction (FEC) encoder; and
cause the STA to transmit the QAM symbol stream within a physical layer protocol data unit (PPDU),
wherein to address a byte boundary shift at a receiving station, the processing circuitry is configured to modify performance of the bit scrambling when probabilistic constellation shaping is performed.

12. The non-transitory computer-readable storage medium of claim 11, wherein for the probabilistic constellation shaping the shaping encoder determines amplitude bit tuples of a fixed length for the shaped bit stream by matching segments of the input bits of different lengths with table entries of a constellation shaping table for the modulation order,
wherein the byte boundary shift is caused a decoding error at the receiving station resulting in an incorrect length for one or more of the segments of the input bits.

13. The non-transitory computer-readable storage medium of claim 12, wherein to address the byte boundary shift, the processing circuitry is to:
refrain from performing the bit scrambling when the probabilistic constellation shaping is performed; and
modify a peak-to-average power ratio (PAPR) at transmission of the QAM symbol stream to at least in part compensate for a PAPR change resulting from the refraining from performing of the bit scrambling.

14. The non-transitory computer-readable storage medium of claim 12, wherein the input bits for the bit scrambling comprise a variable length input data block comprising a variable number of padding bits and a fixed number of valid input bits,
wherein to address the byte boundary shift, the processing circuitry is to:
perform scrambling on the valid input bits and refrain from performing bit scrambling on the padding bits to provide output bit blocks to the shaping encoder.

15. The non-transitory computer-readable storage medium of claim 14, wherein the processing circuitry is to restart a scrambling sequence generator for each input data block for performance of the bit scrambling,
wherein when a scrambling seed that is not known to the receiving station is used for restarting the scrambling sequence generator, the processing circuitry is configured to send the scrambling seed to the receiving station at a beginning of a data field of the PPDU.

16. The non-transitory computer-readable storage medium of claim 12, wherein to address the byte boundary shift, the processing circuitry is to:
insert a tag into the scrambled input bits before performance of the probabilistic constellation shaping, the tag indicating a number of bits; and
restart a scrambling sequence generator for performance of the bit scrambling at each tag,
wherein when a scrambling seed that is not known to the receiving station is used for restarting the scrambling sequence generator, the processing circuitry is configured to send the scrambling seed to the receiving station at a beginning of a data field of the PPDU.

17. The non-transitory computer-readable storage medium of claim 12, wherein the input bits for the bit scrambling comprise a variable length input data block, and
wherein to address the byte boundary shift, the processing circuitry is to:
restrict a number of valid input data bits for the performance of the bit scrambling for each output bit block to a predetermined number; and
restart a scrambling sequence generator for performance of the bit scrambling for each input data block,
wherein when a scrambling seed that is not known to the receiving station is used for restarting the scrambling sequence generator, the processing circuitry is configured to send the scrambling seed to the receiving station without scrambling before each input data block.

18. The non-transitory computer-readable storage medium of claim 12, wherein the PPDU comprises an aggregated MAC protocol data unit (A-MPDU) comprising a plurality of MPDUs and one or more MPDU delimiters,
wherein to address the byte boundary shift, the processing circuitry is to:
restart a scrambling sequence generator for performance of the bit scrambling after each of the MPDU delimiters using a same scrambling seed for each of the MPDUs of the A-MPDU,
wherein when a scrambling seed that is not known to the receiving station is used for restarting the scrambling sequence generator, the processing circuitry is configured to send the scrambling seed to the receiving station before each MPDU.

19. A method performed by processing circuitry of a station (STA) configured for operation in a WLAN, the method comprising:
performing bit scrambling on input bits to generate scrambled input bits;
performing probabilistic constellation shaping on the scrambled input bits by encoding a segment of the scrambled input bits for a modulation order and generate a shaped bit stream,
generating a QAM symbol stream at least from the shaped bit stream and from parity bits using the modulation order;
generating the parity bits from the shaped bit streams;
causing the STA to transmit the QAM symbol stream within a physical layer protocol data unit (PPDU); and
modifying performance of the bit scrambling when probabilistic constellation shaping is performed to address a byte boundary shift at a receiving station.

20. The method of claim 19, wherein for the probabilistic constellation shaping the method includes determining amplitude bit tuples of a fixed length for the shaped bit stream by matching segments of the input bits of different lengths with table entries of a constellation shaping table for the modulation order,
wherein the byte boundary shift is caused a decoding error at the receiving station resulting in an incorrect length for one or more of the segments of the input bits.
